(19) United States
(12) Patent Application Publication
(10) Pub. No.: US 2026/0344547 A1
(43) Pub. Date: Oct. 29, 2026

(54) SEMICONDUCTOR DEVICE

(71) Applicant: ROHM CO., LTD., Kyoto-shi (JP)

(72) Inventor: Nobuo MOTONISHI, Kyoto-shi (JP)

(21) Appl. No.: 19/701,300

(22) Filed: Jun. 8, 2026

Related U.S. Application Data
(63) Continuation of application No. PCT/JP2024/042580, filed on Dec. 2, 2024.

(30) Foreign Application Priority Data
Dec. 15, 2023 (JP) 2023-211826

(51) Int. Cl. H10W 90/00; H10W 70/40; H10W 74/10

(52) U.S. Cl. CPC H10W 90/811; H10W 70/411; H10W 74/111; H10W 90/757

(57) ABSTRACT

A semiconductor device includes a first lead including a first island, a second lead including a second island, a first semiconductor element mounted on the first island, a second semiconductor element mounted on the second island, and a sealing resin. The sealing resin covers at least a portion of each of the first lead and the second lead and also covers the first semiconductor element and the second semiconductor element. The first island is located on a first side in a first direction relative to the second island. The first semiconductor element is located on a second side in the first direction relative to the first island. The second semiconductor element is located on the first side in the first direction relative to the second island.

### TECHNICAL FIELD

The present disclosure relates to a semiconductor device.

### BACKGROUND ART

JP-A-2023-138181 discloses an example of a conventional semiconductor device. The semiconductor device disclosed in JP-A-2023-138181 includes a first lead, a second lead, a semiconductor element, and a sealing resin. The semiconductor element is mounted on the first lead. The semiconductor element and the second lead are connected with a wire. The sealing resin covers the semiconductor element.

### BRIEF DESCRIPTION OF THE DRAWINGS

FIG. 1 is a plan view of a semiconductor device according to a first embodiment of the present disclosure.

FIG. 2 is a front view of a semiconductor device according to the first embodiment of the present disclosure.

FIG. 3 is a partial plan view of the semiconductor device according to the first embodiment of the present disclosure.

FIG. 4 is a partial plan view of the semiconductor device according to the first embodiment of the present disclosure.

FIG. 5 is a sectional view taken along line V-V in FIG. 3.

FIG. 6 is a sectional view taken along line VI-VI in FIG. 3.

FIG. 7 is a partial enlarged sectional view of the semiconductor device according to the first embodiment of the present disclosure.

FIG. 8 is a partial enlarged sectional view of a first variation of the semiconductor device according to the first embodiment of the present disclosure.

FIG. 9 is a partial plan view of a semiconductor device according to a second embodiment of the present disclosure.

FIG. 10 is a sectional view taken along line X-X in FIG. 9.

FIG. 11 is a partial plan view of a semiconductor device according to a third embodiment of the present disclosure.

FIG. 12 is a partial plan view of the semiconductor device according to the third embodiment of the present disclosure.

FIG. 13 is a sectional view taken along line XIII-XIII in FIG. 11.

FIG. 14 is a sectional view taken along line XIV-XIV in FIG. 11.

FIG. 15 is a sectional view taken along line XV-XV in FIG. 11.

FIG. 16 is a partial plan view of a first variation of the semiconductor device according to the third embodiment of the present disclosure.

FIG. 17 is a sectional view taken along line XVII-XVII in FIG. 16.

FIG. 18 is a partial plan view of a semiconductor device according to a fourth embodiment of the present disclosure.

FIG. 19 is a partial plan view of the semiconductor device according to the fourth embodiment of the present disclosure.

FIG. 20 is a sectional view taken along line XX-XX in FIG. 18.

FIG. 21 is a sectional view taken along line XXI-XXI in FIG. 18.

FIG. 22 is a sectional view of a semiconductor device according to a fifth embodiment of the present disclosure.

FIG. 23 is a sectional view of a semiconductor device according to the fifth embodiment of the present disclosure.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

### First embodiment

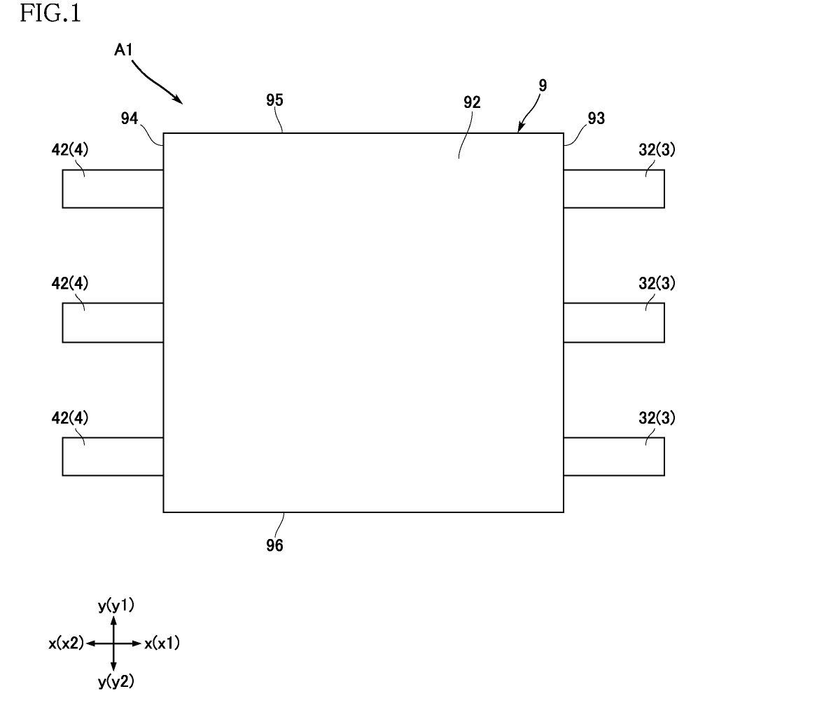

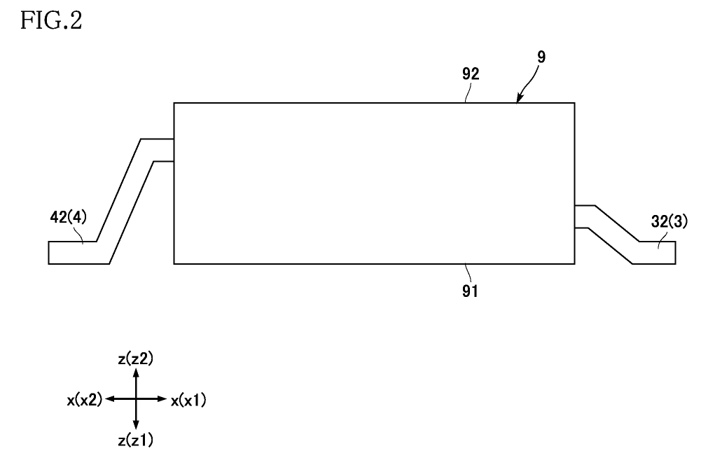

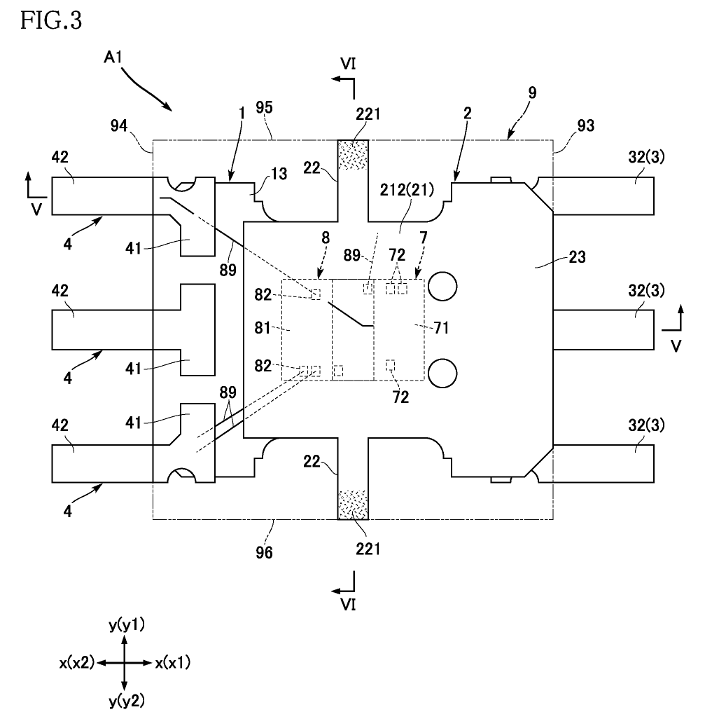

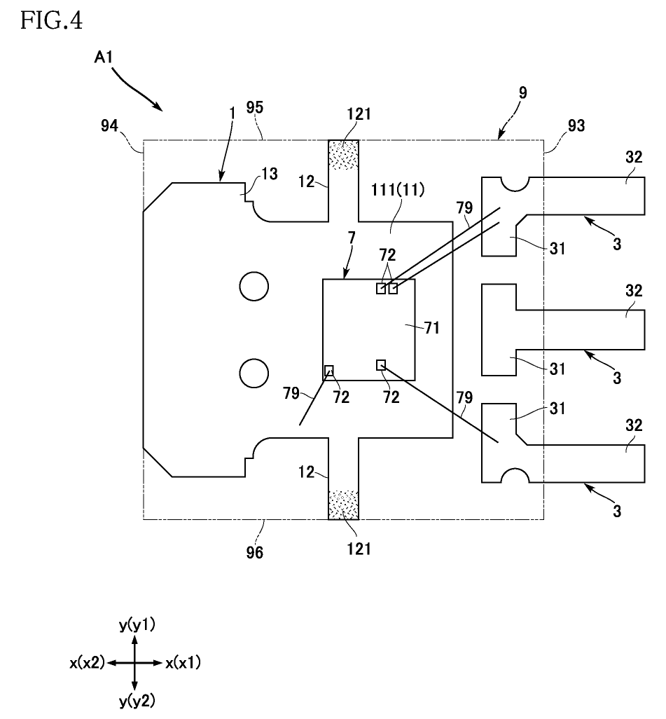

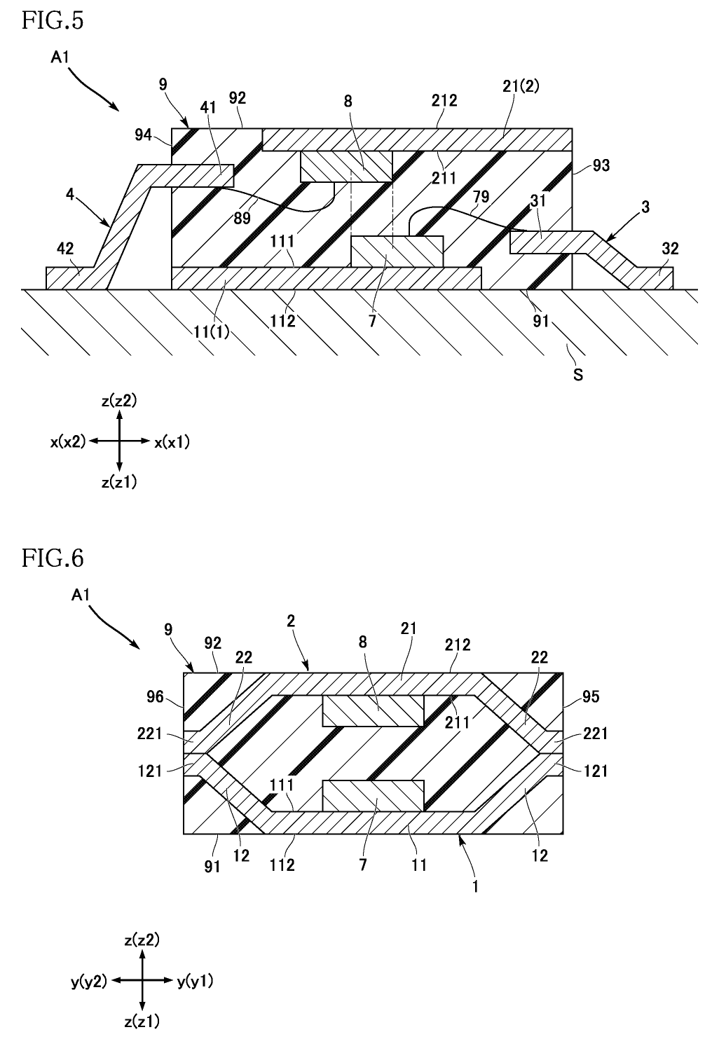

FIGS. 1-7 show a semiconductor device according to a first embodiment of the present disclosure. The semiconductor device A1 of the present embodiment includes a first lead 1, a second lead 2, a first semiconductor element 7, a second semiconductor element 8, and a sealing resin 9. The semiconductor device A1 may include one or more third leads 3 and one or more fourth leads 4. The specific functions and applications of the semiconductor device A1 are not particularly limited.

In these figures, reference is made as appropriate to three mutually orthogonal directions (the x direction, the y direction, and the z direction). As an example, the z direction may correspond to the first direction of the present disclosure. The x direction may correspond to the second direction of the present disclosure. The y direction is orthogonal to the z direction and the x direction.

The sealing resin 9 covers a portion of each of the first lead 1, the second lead 2, one or more third leads 3, and one or more fourth leads 4, and also covers the first semiconductor element 7 and the second semiconductor element 8. The material of the sealing resin 9 is not particularly limited and may, for example, be an epoxy resin.

The sealing resin 9 may have a resin first surface 91, a resin second surface 92, a resin third surface 93, a resin fourth surface 94, a resin fifth surface 95, and a resin sixth surface 96.

The resin first surface 91 faces the z1 side in the z direction. The resin second surface 92 faces the z2 side in the z direction. The resin third surface 93 faces the x1 side in the x direction. The resin fourth surface 94 faces the x2 side in the x direction. The resin fifth surface 95 faces the y1 side in the y direction. The resin sixth surface 96 faces the y2 side in the y direction. Each of the resin first surface 91, the resin second surface 92, the resin third surface 93, the resin fourth surface 94, the resin fifth surface 95, and the resin sixth surface 96 may be a flat surface, or may be an inclined surface, a curved surface, or the like.

The first lead 1 has a first island 11. The first lead 1 may have one or more first support portions 12 and a first extension portion 13. The first lead 1 may contain a metal such as Cu (copper), Ni (nickel), Fe (iron), or alloys thereof. A metal layer containing, for example, Ag (silver) may be formed at appropriate portions on the first lead 1 by plating, for example. The thickness of the first lead 1 is not particularly limited and may be, for example, 400 μm or more and 600 μm or less.

The first island 11 is a region having a thickness in the z direction and extending along the x direction and the y direction. The first island 11 has a first obverse surface 111 and a first reverse surface 112. The first obverse surface 111 faces the z2 side in the z direction, and is a flat surface in the illustrated example. The first reverse surface 112 faces the z1 side in the z direction, and is flat surface in the illustrated example. In the illustrated example, the first reverse surface 112 is exposed from the resin first surface 91. The first reverse surface 112 may be flush with the resin first surface 91.

The one or more first support portions 12 are connected to the first island 11. The number of one or more first support portions 12 is not particularly limited, and is two in the illustrated example. The two first support portions 12 extend from the first island 11 toward the y1 side and the y2 side in the y direction. A first support portion 12 has a first facing part 121. The first facing part 121 is located on the z2 side of the first island 11 in the z direction.

The first extension portion 13 is connected to the first island 11. In the illustrated example, the first extension portion 13 extends from the first island 11 toward the x2 side in the x direction.

The second lead 2 has a second island 21. The second lead 2 may have one or more second support portions 22 and a second extension portion 23. The second lead 2 may contain a metal such as Cu (copper), Ni (nickel), Fe (iron), or alloys thereof. A metal layer containing, for example, Ag (silver) may be formed at appropriate portions on the second lead 2 by plating, for example. The thickness of the second lead 2 is not particularly limited and may be, for example, 400 μm or more and 600 μm or less.

The second island 21 is a region having a thickness in the z direction and extending along the x direction and the y direction. The second island 21 has a second obverse surface 211 and a second reverse surface 212. The second obverse surface 211 faces the z1 side in the z direction, and is flat surface in the illustrated example. The second obverse surface 211 faces the first obverse surface 111. The second reverse surface 212 faces the z2 side in the z direction, and is flat surface in the illustrated example. In the illustrated example, the second reverse surface 212 is exposed from the resin second surface 92. The second reverse surface 212 may be flush with the resin second surface 92.

The first island 11 is located on the z1 side in the z direction relative to the second island 21. In other words, the second island 21 is located on the z2 side in the z direction relative to the first island 11. The first island 11 and the second island 21 at least partially overlap with each other as viewed in the z direction.

The one or more second support portions 22 are connected to the second island 21. The number of one or more second support portions 22 is not particularly limited, and is two in the illustrated example. The two second support portions 22 extend from the second island 21 toward the y1 side and the y2 side in the y direction. A second support portion 22 has a second facing part 221. The second facing part 221 is located on the z1 side of the second island 21 in the z direction.

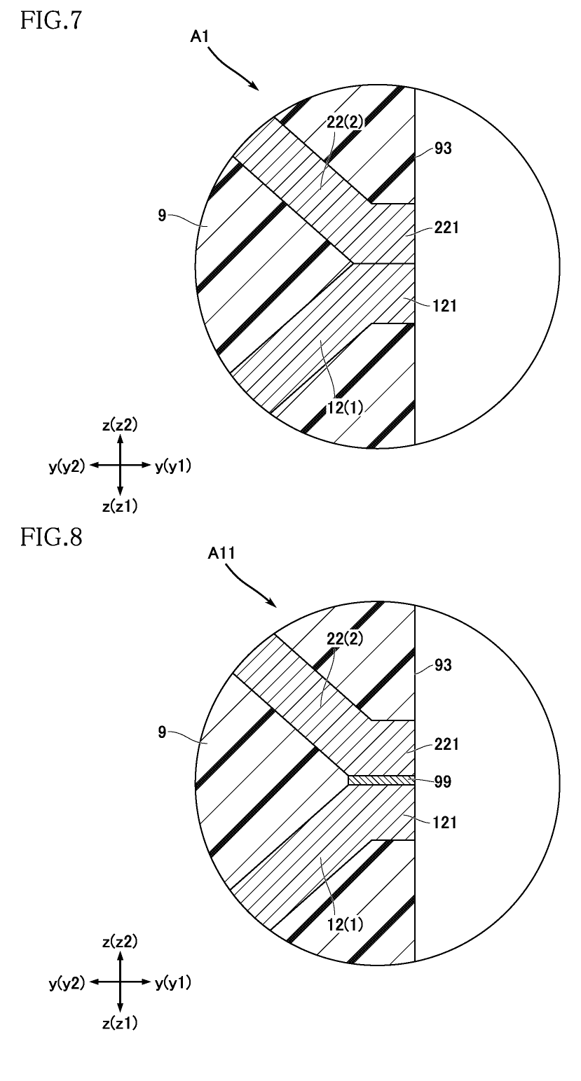

As shown in FIG. 6, the first facing part 121 and the second facing part 221 face each other in the z direction. The first facing part 121 and the second facing part 221 may be spaced apart or may be in contact with each other. A bonding material may be interposed between the first facing part 121 and the second facing part 221. In the example shown in FIG. 7, the first facing part 121 and the second facing part 221 are in direct contact with each other.

The second extension portion 23 is connected to the second island 21. In the illustrated example, the second extension portion 23 extends from the second island 21 toward the x1 side in the x direction.

The one or more third leads 3 have the first island 11. The one or more third leads 3 may have one or more first support portions 12 and a first extension portion 13. The one or more third leads 3 may contain a metal such as Cu (copper), Ni (nickel), Fe (iron), or alloys thereof. A metal layer containing, for example, Ag (silver) may be formed at appropriate portions on the one or more third leads 3 by plating, for example. The thickness of the third lead(s) 3 is not particularly limited and may be, for example, 400 μm or more and 600 μm or less.

The number of one or more third leads 3 is not particularly limited, and is three in the illustrated example. The three third leads 3 are located on the x1 side in the x direction relative to the first island 11. A third lead 3 has a pad portion 31 and a third terminal portion 32. The pad portion 31 is covered with the sealing resin 9 and used to establish electrical connection with the first semiconductor element 7. The pad portion 31 is located on the z2 side of the first island 11 in the z direction. The third terminal portion 32 protrudes from the resin third surface 93 toward the x1 side in the x direction. The extremity of the third terminal portion 32 is located at the same position as the first island 11 in the z direction.

The one or more fourth leads 4 have the first island 11. The one or more fourth leads 4 may have one or more first support portions 12 and a first extension portion 13. The one or more fourth leads 4 may contain a metal such as Cu (copper), Ni (nickel), Fe (iron), or alloys thereof. A metal layer containing, for example, Ag (silver) may be formed at appropriate portions on the one or more fourth leads 4 by plating, for example. The thickness of the fourth lead(s) 4 is not particularly limited and may be, for example, 400 μm or more and 600 μm or less.

The number of one or more fourth leads 4 is not particularly limited, and is three in the illustrated example. The three fourth leads 4 are located on the x2 side in the x direction relative to the second island 21. A fourth lead 4 has a pad portion 41 and a terminal portion 42. The pad portion 41 is covered with the sealing resin 9 and used to establish electrical connection with the second semiconductor element 8. The pad portion 41 is located on the z1 side of the second island 21 in the z direction. The terminal portion 42 protrudes from the resin fourth surface 94 toward the x2 side in the x direction. The extremity of the terminal portion 42 is located at the same position as the first island 11 and the third terminal portion 32 in the z direction.

The first semiconductor element 7 is mounted on the first obverse surface 111 of the first island 11. The first semiconductor element 7 is located on the z2 side in the z direction relative to the first island 11. The first semiconductor element 7 is located on the z1 side in the z direction relative to the second island 21. The type and function of the first semiconductor element 7 are not particularly limited. In the illustrated example, the first semiconductor element 7 is configured, for example, as an LDO (Low Dropout) regulator.

The first semiconductor element 7 may have a first main body 71 and a plurality of first electrodes 72. The first main body 71 contains a semiconductor and, for example, incorporates a functional portion. The first electrodes 72 are located on the first main body 71. At least one of the first electrodes 72 is connected to the pad portion 31 of one of the three third leads 3 with one of a plurality of first wires 79. The first wires 79 extend from the first semiconductor element 7 toward the x1 side in the x direction.

The second semiconductor element 8 is mounted on the second obverse surface 211 of the second island 21. The second semiconductor element 8 is located on the z1 side in the z direction relative to the second island 21. The second semiconductor element 8 is located on the z2 side in the z direction relative to the first island 11. In the illustrated example, the entire second semiconductor element 8 is located on the z2 side in the z direction relative to the first semiconductor element 7. In the illustrated example, as viewed in the z direction, the first semiconductor element 7 and the second semiconductor element 8 at least partially overlap with each other. The type and function of the second semiconductor element 8 are not particularly limited. In the illustrated example, the second semiconductor element 8 is configured, for example, as an operational amplifier.

The second semiconductor element 8 may have a second main body 81 and a plurality of second electrodes 82. The second main body 81 contains a semiconductor and, for example, incorporates a functional portion. The second electrodes 82 are located on the second main body 81. At least one of the second electrodes 82 is connected to the pad portion 41 of one of the three fourth leads 4 with one of a plurality of second wires 89. The second wires 89 extend from the second semiconductor element 8 toward the x2 side in the x direction.

The method for manufacturing the semiconductor device A1 is not particularly limited. According to an example of a method for manufacturing the semiconductor device A1, a lead frame including the first lead 1 and one or more third leads 3 is prepared. The first semiconductor element 7 is mounted on the lead frame, and a plurality of first wires 79 are connected. Another lead frame including the second lead 2 and one or more fourth leads 4 is prepared. The second semiconductor element 8 is mounted on this another lead frame, and a plurality of second wires 89 are connected. Next, these two lead frames are stacked on top of each other. At this time, the two lead frames are stacked in such a manner that the first facing part 121 and the second facing part 221 are brought into contact with each other. Next, a sealing resin 9 is formed, and the two lead frames are cut at appropriate portions as necessary. Thus, the semiconductor device A1 is obtained.

Next, the effects of the semiconductor device A1 will be described.

In the semiconductor device A1, the first island 11 is located on the z1 side in the z direction relative to the second island 21. The first semiconductor element 7 is located on the z2 side in the z direction relative to the first island 11. The second semiconductor element 8 is located on the z1 side in the z direction relative to the second island 21. That is, the first island 11 and the second island 21 are spaced apart from each other in the z direction, and the first semiconductor element 7 and the second semiconductor element 8 are located between them. Thus, when mounting the semiconductor device A1 on a mounting board S or the like, the mounting space can be reduced compared to the case where a semiconductor device including a first semiconductor element 7 and another semiconductor device including a second semiconductor element 8 are mounted on the mounting substrate S.

The third lead 3 is located on the x1 side in the x direction relative to the first island 11. The fourth lead 4 is located on the x2 side in the x direction relative to the second island 21. Thus, the third lead 3 and the fourth lead 4 are located on opposite sides in the x direction, flanking the first island 11 and the second island 21. Therefore, interference between the third lead 3 and the fourth lead 4 can be avoided. Similarly, interference between the first wires 79 and the second wires 89 can be avoided.

The first facing part 121 and the second facing part 221 face each other and are in contact with each other. Thus, when two lead frames are used in the manufacturing method for the semiconductor device A1, the positions of the two lead frames in the z direction can be set more accurately. Therefore, it is possible to more reliably and easily achieve the configuration in which the first island 11 and the second island 21 are spaced apart in the z direction, with the first semiconductor element 7 and the second semiconductor element 8 located between them.

The first semiconductor element 7 and the second semiconductor element 8 overlap at least partially as viewed in the z direction. This can further reduce the mounting space of the semiconductor device A1.

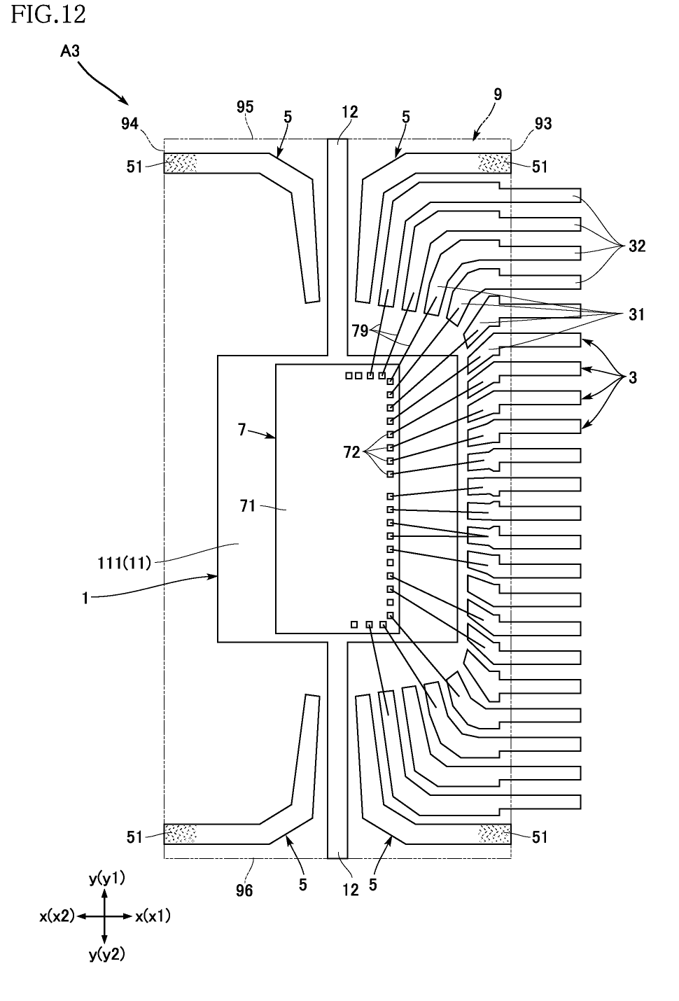

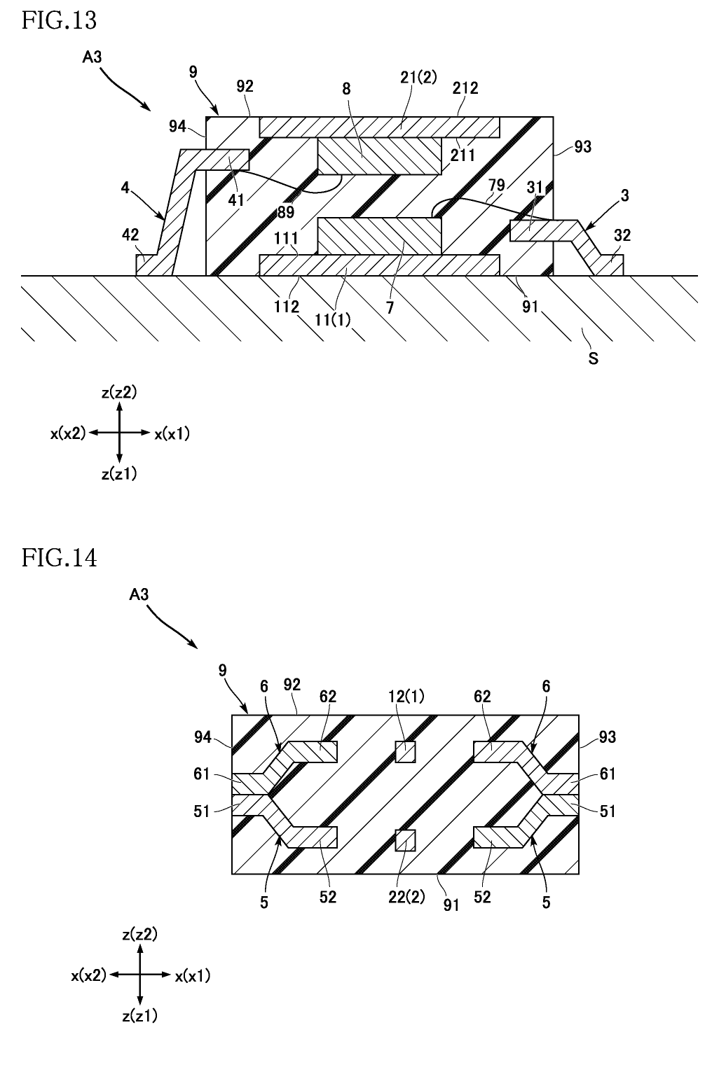

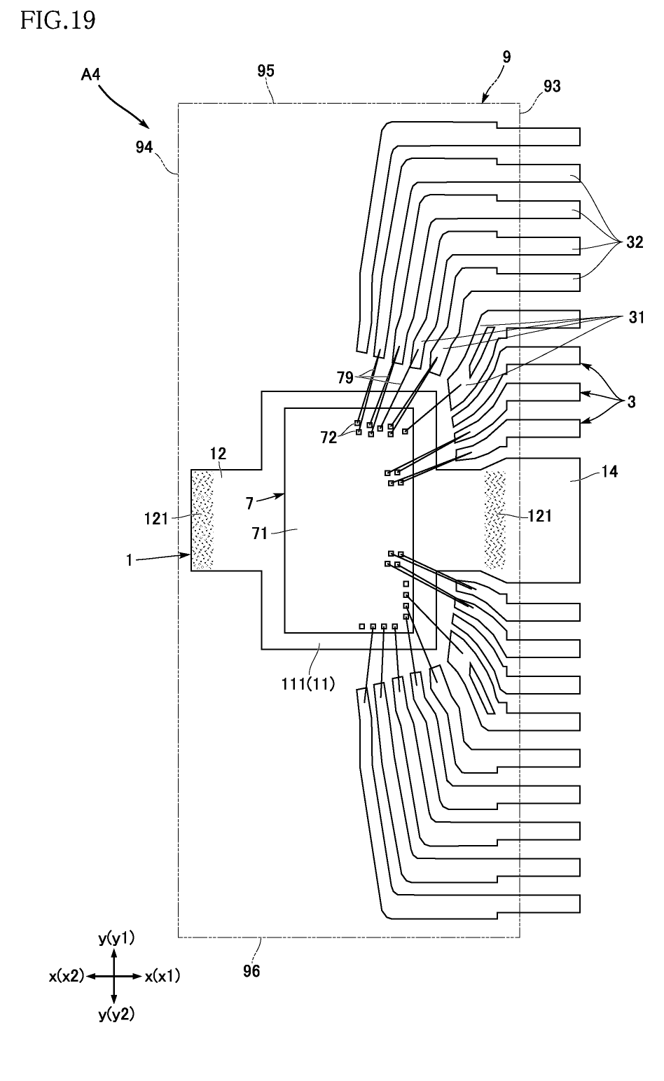

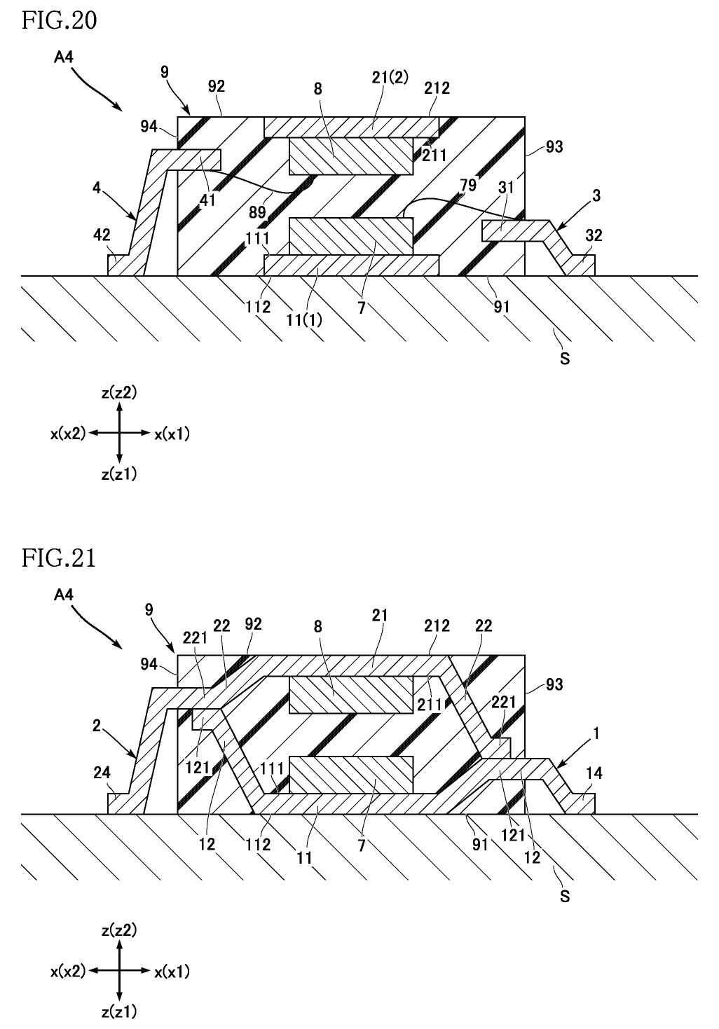

FIGS. 8-21 show variations and other embodiments of the present disclosure. In these figures, the elements that are identical or similar to those of the embodiment described above are denoted by the same reference signs, and the descriptions thereof are omitted. Various parts of variations and embodiments may be selectively used in any appropriate combination as long as it is technically compatible.

### First embodiment, first variation

FIG. 8 shows a first variation of the semiconductor device A1. In the semiconductor device A11 of the present variation, a bonding material 99 is interposed between the first facing part 121 and the second facing part 221. The sealing resin 9 may serve to bond the first facing part 121 and the second facing part 221. The bonding material 99 may be conductive or insulating.

The present variation can reduce the mounting space of the semiconductor device A11. As understood from the present variation, the specific configuration in which the first facing part 121 and the second facing part 221 face each other is not particularly limited.

### Second Embodiment

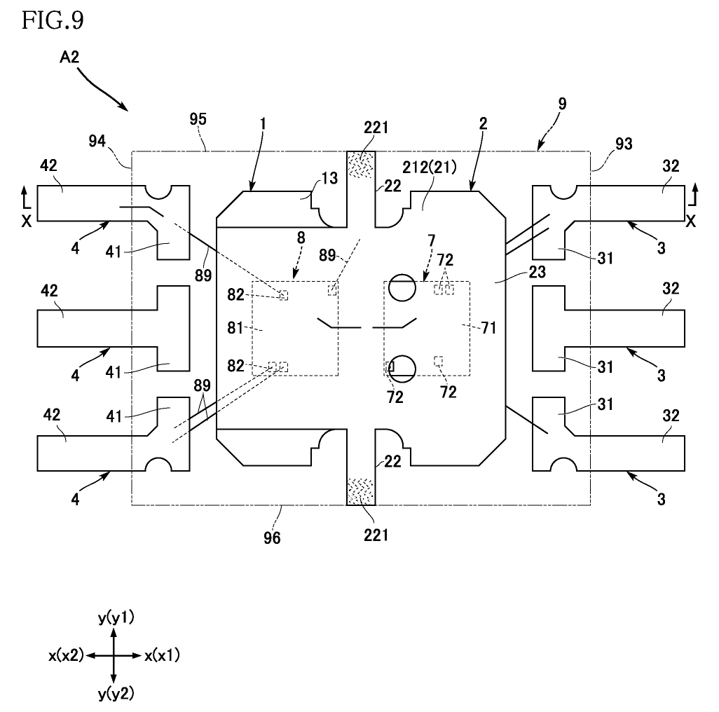

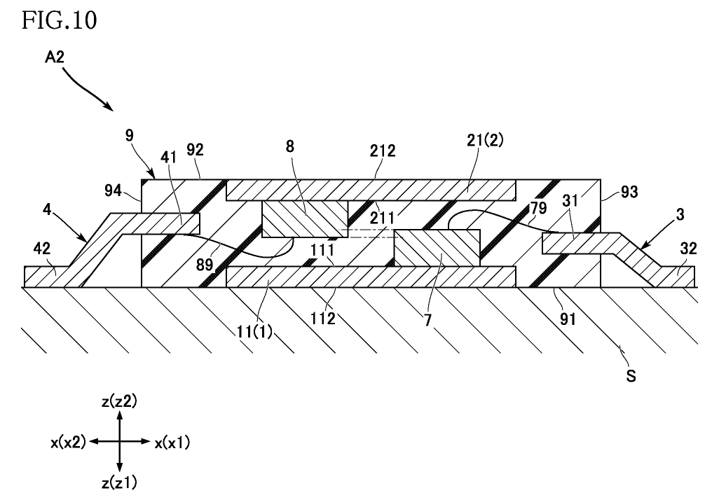

FIGS. 9 and 10 show a semiconductor device according to a second embodiment of the present disclosure. The semiconductor device A2 of the present embodiment includes a first semiconductor element 7 and a second semiconductor element 8 that are spaced apart from each other as viewed in the z direction. The first semiconductor element 7 and the second semiconductor element 8 at least partially overlap with each other as viewed in the x direction.

In the illustrated example, as viewed in the z direction, at least a portion of the first semiconductor element 7 may overlap with the second lead 2, or the entire first semiconductor element 7 may overlap with the second lead 2. In the illustrated example, as viewed in the z direction, at least a portion of the second semiconductor element 8 may overlap with the first lead 1, or the entire second semiconductor element 8 may overlap with the first lead 1.

The present embodiment can reduce the mounting space of the semiconductor device A2. Because the first semiconductor element 7 and the second semiconductor element 8 are spaced apart as viewed in the z direction and at least partially overlap with each other as viewed in the x direction, the dimension in the z direction of the semiconductor device A2 can be reduced.

### Third Embodiment

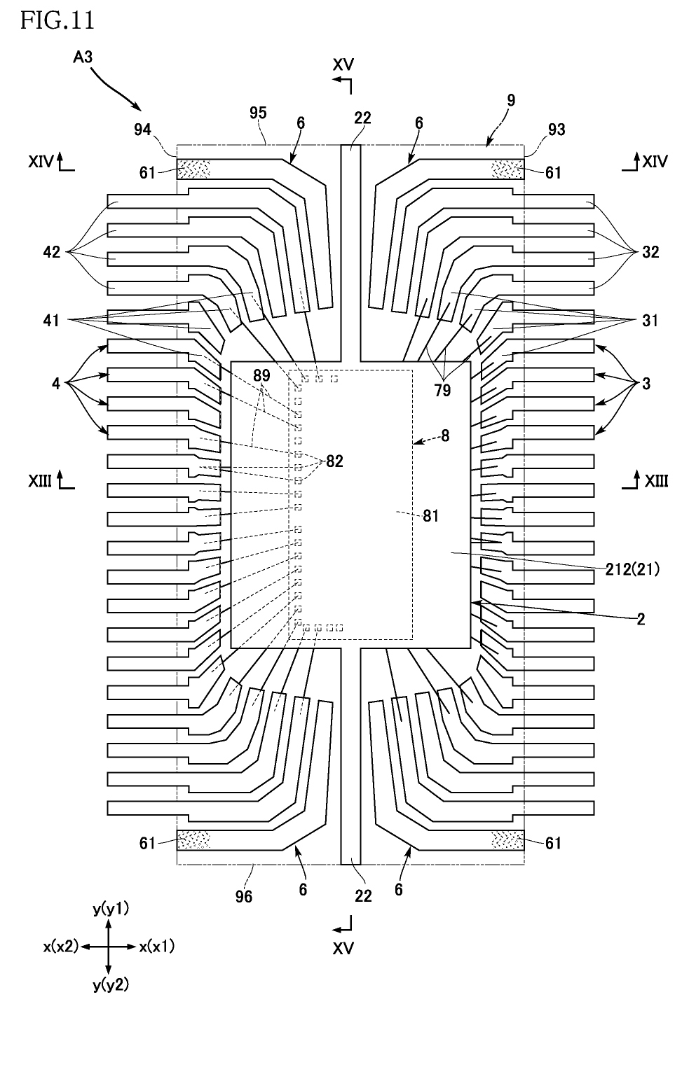

FIGS. 11-15 show a semiconductor device according to a third embodiment of the present disclosure. The semiconductor device A3 of the present embodiment includes a first lead 1, a second lead 2, a plurality of third leads 3, a plurality of fourth leads 4, one or more fifth leads 5, one or more sixth leads 6, and a sealing resin 9.

The first semiconductor element 7 and the second semiconductor element 8 of the present embodiment are, for example, LED (Light Emitting Diode) drivers. The first electrodes 72 of the first semiconductor element 7 are individually connected to the pad portions 31 of the third leads 3 with first wires 79. The second electrodes 82 of the second semiconductor element 8 are individually connected to the pad portions 41 of the fourth leads 4 with second wires 89.

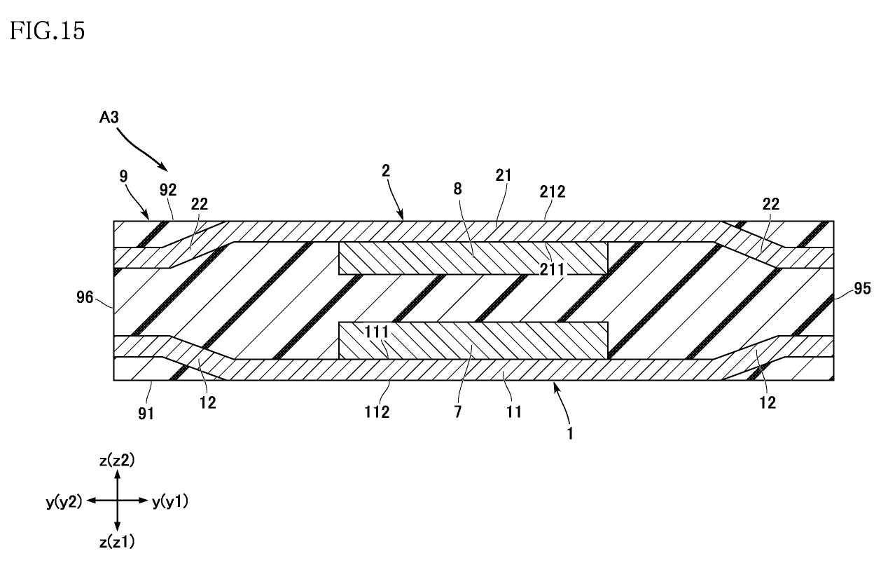

As shown in FIG. 15, in the present embodiment, the first support portion 12 and the second support portion 22 are spaced apart from each other.

The one or more fifth leads 5 are not electrically connected to the first semiconductor element 7 and the second semiconductor element 8. The material and thickness of the one or more fifth leads 5 may be the same as those of the third lead 3, for example. The number of one or more fifth leads 5 is not particularly limited, and is four in the illustrated example. The arrangement of the four fifth leads 5 is not particularly limited. In the illustrated example, two of the fifth leads 5 are located on opposite sides of one of the first support portions 12 in the x direction, and the other two fifth leads 5 are located on opposite sides of the other first support portion 12 in the x direction.

A fifth lead 5 may include a third facing part 51 and a spaced portion 52. The spaced portion 52 is located on the z2 side in the z direction relative to the first island 11. The spaced portion 52 may be at the same position as the pad portion 31 in the z direction. The third facing part 51 is located on the z2 side in the z direction relative to the first island 11 and the spaced portion 52.

The one or more sixth leads 6 are not electrically connected to the first semiconductor element 7 and the second semiconductor element 8. The material and thickness of the one or more sixth leads 6 may be the same as those of the fourth leads 4, for example. The number of one or more sixth leads 6 is not particularly limited, and is four in the illustrated example. The arrangement of the four sixth leads 6 is not particularly limited. In the illustrated example, two of the sixth leads 6 are located on opposite sides of one of the second support portions 22 in the x direction, and the other two sixth leads 6 are located on opposite sides of the other second support portion 22 in the x direction.

A sixth lead 6 may include a fourth facing part 61 and a spaced portion 62. The spaced portion 62 is located on the z1 side in the z direction relative to the second island 21. The spaced portion 62 may be at the same position as the pad portion 41 in the z direction. The fourth facing part 61 is located on the z1 side in the z direction relative to the second island 21 and the spaced portion 62.

As shown in FIG. 14, the third facing part 51 and the fourth facing part 61 face each other in the z direction. The third facing part 51 and the fourth facing part 61 may be spaced apart or may be in contact with each other. A bonding material may be interposed between the third facing part 51 and the fourth facing part 61. In the example shown in FIG. 14, the third facing part 51 and the fourth facing part 61 are in direct contact with each other. In the illustrated example, the third facing part 51 and the fourth facing part 61 are covered with the sealing resin 9.

The present embodiment can reduce the mounting space of the semiconductor device A3. By configuring the third facing part 51 of the fifth lead 5 and the fourth facing part 61 of the sixth lead 6 to face each other, it is possible to achieve a configuration in which the first semiconductor element 7 and the second semiconductor element 8 are located at different positions in the z direction.

### Third embodiment, first variation

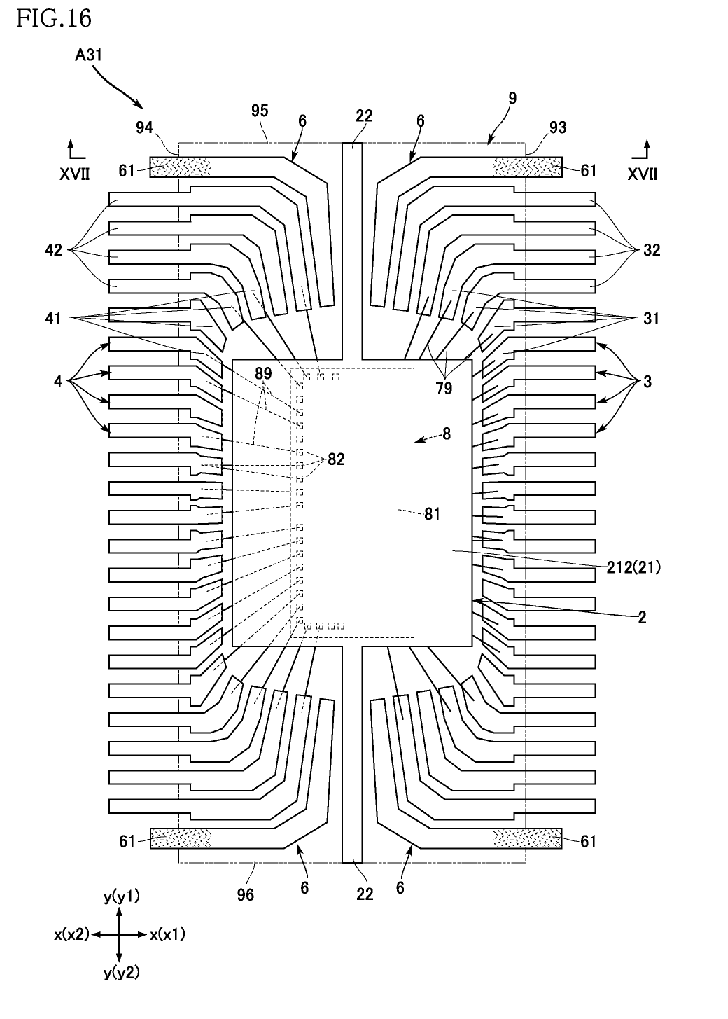

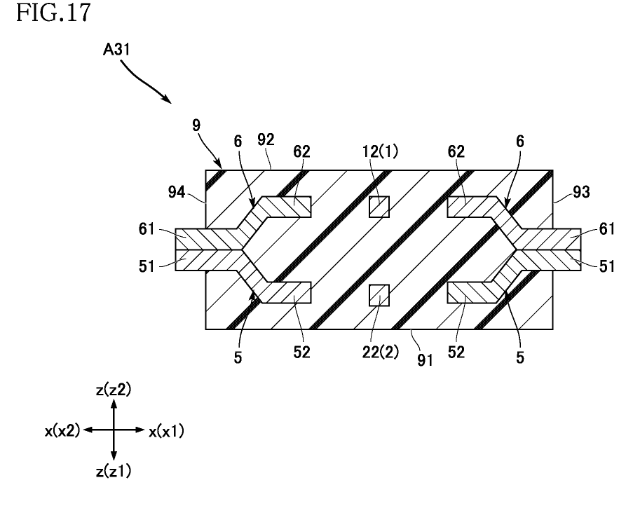

FIGS. 16 and 17 show a first variation of the semiconductor device according to the third embodiment of the present disclosure. In the semiconductor device A31 of the present variation, a portion of each of the third facing part 51 and the fourth facing part 61 protrudes from the sealing resin 9.

In the illustrated example, two third facing parts 51 and two fourth facing parts 61 protrude from the resin third surface 93 toward the x1 side in the x direction. The other two third facing parts 51 and the other two fourth facing parts 61 protrude from the resin fourth surface 94 toward the x2 side in the x direction.

The present variation can reduce the mounting space of the semiconductor device A31. As understood from the present variation, the specific configurations of the third facing part 51 and the fourth facing part 61 are not particularly limited.

### Fourth Embodiment

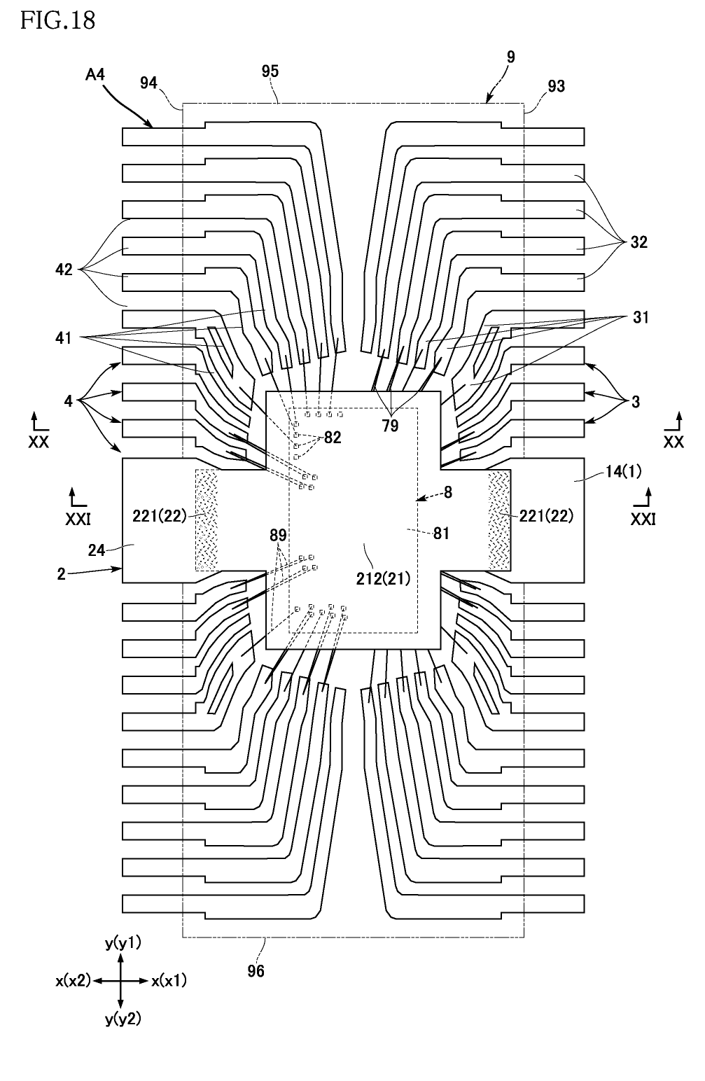

FIGS. 18-21 show a semiconductor device according to a fourth embodiment of the present disclosure. In the semiconductor device A4 of the present embodiment, the first lead 1 includes a first island 11, two first support portions 12, and a first terminal portion 14.

The two first support portions 12 extend from the first island 11 toward the opposite sides in the x direction. The first terminal portion 14 is connected to the first support portion 12 located on the x1 side in the x direction, out of the two first support portions 12. The extremity of the first terminal portion 14 is located at the same position as the first island 11 in the z direction.

Each of the two first support portions 12 has a first facing part 121. The first facing part 121 on the x1 side in the x direction is located on the z2 side of the first island 11 in the z direction. This first facing part 121 may be at the same position as the pad portions 31 of the third leads 3 in the z direction.

The first facing part 121 on the x2 side in the x direction is located on the z2 side of the first island 11 and the other first facing part 121 in the z direction. This first facing part 121 is located on the z2 side of the first semiconductor element 7 in the z direction.

In the semiconductor device A4, the second lead 2 includes a second island 21, two second support portions 22, and a second terminal portion 24.

The two second support portions 22 extend from the second island 21 toward the opposite sides in the x direction. The second terminal portion 24 is connected to the second support portion 22 located on the x2 side in the x direction, out of the two second support portions 22. The extremity of the second terminal portion 24 is located at the same position as the first island 11 and the first terminal portion 14 in the z direction.

Each of the two second support portions 22 has a second facing part 221. The second facing part 221 on the x2 side in the x direction is located on the z1 side of the second island 21 in the z direction. This second facing part 221 may be at the same position as the pad portions 41 of the fourth leads 4 in the z direction.

The second facing part 221 on the x1 side in the x direction is located on the z1 side of the second island 21 and the other second facing part 221 in the z direction. This second facing part 221 is located on the z2 side of the second semiconductor element 8 in the z direction.

Each of the first facing parts 121 faces a relevant second facing part 221 in the z direction. The first facing part 121 and the second facing part 221 may be spaced apart or may be in contact with each other. A bonding material may be interposed between the first facing part 121 and the second facing part 221. In the example shown in FIG. 7, the first facing part 121 and the second facing part 221 are in direct contact with each other.

The present embodiment can reduce the mounting space of the semiconductor device A4. By conductively bonding the first terminal portion 14 and the second terminal portion 24 to the wiring pattern (not shown) on the mounting board S, the first lead 1 and the second lead 2 can be electrically connected to the appropriate portions on the mounting board S. The first terminal portion 14 and the second terminal portion 24 are electrically connected, for example, to the ground line (not shown) of the mounting board S.

### Fifth Embodiment

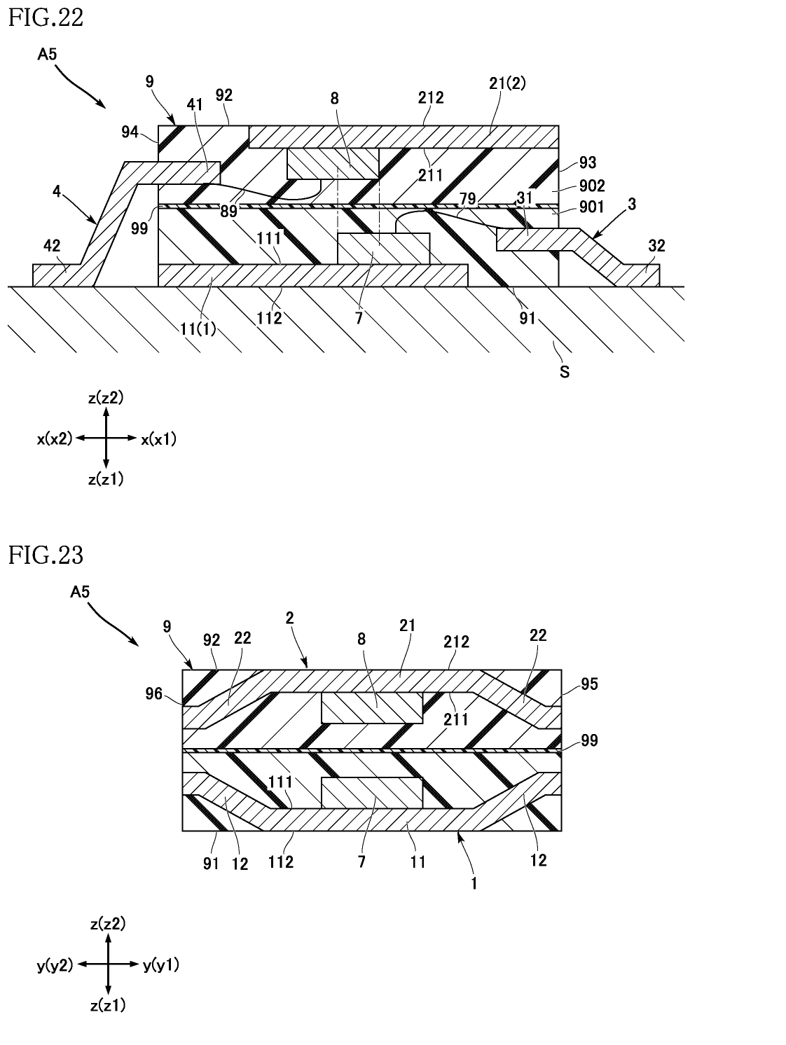

FIGS. 22 and 23 show a semiconductor device according to a fifth embodiment of the present disclosure. In the semiconductor device A5 of the present embodiment, the sealing resin 9 includes a first resin portion 901 and a second resin portion 902.

The first resin portion 901 covers a portion of each of the first lead 1 and one or more third leads 3, and also covers the first semiconductor element 7 and the first wires 79. The second resin portion 902 covers a portion of each of the second lead 2 and one or more fourth leads 4, and also covers the second semiconductor element 8 and the second wires 89.

The first resin portion 901 is located on the z1 side in the z direction relative to the second resin portion 902. The first resin portion 901 and the second resin portion 902 face each other in the z direction. In the illustrated example, the first resin portion 901 and the second resin portion 902 are bonded with a bonding material 99. The bonding material 99 is, for example, a resin bonding material.

According to an example of a method for manufacturing the semiconductor device A5, the first semiconductor element 7 and the first wires 79 are connected to the first lead 1 and the one or more third leads 3, and the first resin portion 901 is formed. The second semiconductor element 8 and the second wires 89 are connected to the second lead 2 and the one or more fourth leads 4, and the second resin portion 902 is formed. Next, the first resin portion 901 and the second resin portion 902 are bonded with a bonding material 99, thereby providing the semiconductor device A5.

The present embodiment can reduce the mounting space of the semiconductor device A5. As understood from the present embodiment, the sealing resin 9 may be formed integrally as a single unit or may consist of the first resin portion 901 and the second resin portion 902 formed separately and bonded together.

The semiconductor device according to the present disclosure is not limited to the above-described embodiments. Various modifications in design may be made freely in the specific structure of each part of the semiconductor device according to the present disclosure. The present disclosure includes embodiments described in the following clauses.

Clause 1. A semiconductor device (A1) comprising:
a first lead (1) including a first island (11);
a second lead (2) including a second island (21);
a first semiconductor element (7) mounted on the first island (11);
a second semiconductor element (8) mounted on the second island (21); and
a sealing resin (9) covering at least a portion of each of the first lead (1) and the second lead (2) and also covering the first semiconductor element (7) and the second semiconductor element (8), wherein
the first island (11) is located on a first side (z1) in a first direction (z) relative to the second island (21),
the first semiconductor element (7) is located on a second side (z2) in the first direction (z) relative to the first island (11), and
the second semiconductor element (8) is located on the first side (z1) in the first direction (z) relative to the second island (21).

Clause 2. The semiconductor device (A1) according to clause 1, further comprising:
a third lead (3) electrically connected to the first semiconductor element (7); and
a fourth lead (4) electrically connected to the second semiconductor element (8), wherein
the third lead (3) is located on a first side (x1) in a second direction (x) relative to the first island (11), the second direction (x) being orthogonal to the first direction (z), and
the fourth lead (4) is located on a second side (x2) in the second direction (x) relative to the second island (21).

Clause 3. The semiconductor device (A1) according to clause 2, further comprising a first wire (79) connected to the first semiconductor element (7) and the third lead (3).

Clause 4. The semiconductor device (A1) according to clause 2 or 3, further comprising a second wire (89) connected to the second semiconductor element (8) and the fourth lead (4).

Clause 5. The semiconductor device (A1) according to any one of clauses 2 to 4, wherein the third lead (3) includes a terminal portion (32) protruding from the sealing resin (9) toward the first side (x1) in the second direction (x).

Clause 6. The semiconductor device (A1) according to any one of clauses 2 to 5, wherein the fourth lead (4) includes a terminal portion (42) protruding from the sealing resin (9) toward the second side (x2) in the second direction (x).

Clause 7. The semiconductor device (A1) according to any one of clauses 1 to 6, wherein the first lead (1) includes a first support portion (12) connected to the first island (11),
the second lead (2) includes a second support portion (22) connected to the second island (21),
the first support portion (12) includes a first facing part (121),
the second support portion (22) includes a second facing part (221), and
the first facing part (121) and the second facing part (221) face each other in the first direction (z).

Clause 8. The semiconductor device (A1) according to clause 7, further comprising a bonding material (99) that bonds the first facing part (121) and the second facing part (221).

Clause 9. The semiconductor device (A1) according to any one of clauses 1 to 8, wherein the first semiconductor element (7) and the second semiconductor element (8) at least partially overlap with each other as viewed in the first direction (z).

Clause 10. The semiconductor device (A11) according to any one of clauses 1 to 8, wherein the first semiconductor element (7) and the second semiconductor element (8) are spaced apart from each other as viewed in the first direction (z).

Clause 11. The semiconductor device (A11) according to clause 10, wherein the first semiconductor element (7) and the second semiconductor element (8) at least partially overlap with each other as viewed in a direction orthogonal to the first direction (z).

Clause 12. The semiconductor device (A1) according to any one of clauses 1 to 11, wherein the first island (11) is exposed from the sealing resin (9) to the first side (z1) in the first direction (z).

Clause 13. The semiconductor device (A1) according to any one of clauses 1 to 12, wherein the second island (21) is exposed from the sealing resin (9) to the second side (z2) in the first direction (z).

Clause 14. The semiconductor device (A3) according to any one of clauses 1 to 13, further comprising a fifth lead (5) including a third facing part (51) and a sixth lead (6) including a fourth facing part (61), wherein
the third facing part (51) is located on the first side (z1) in the first direction (z) relative to the fourth facing part (61), and
the third facing part (51) and the fourth facing part (61) face each other in the first direction (z).

Clause 15. The semiconductor device (A3) according to clause 14, wherein the fifth lead (5) and the sixth lead (6) are insulated from both the first semiconductor element (7) and the second semiconductor element (8).

1. A semiconductor device comprising:
a first lead including a first island;
a second lead including a second island;
a first semiconductor element mounted on the first island;
a second semiconductor element mounted on the second island; and
a sealing resin covering at least a portion of each of the first lead and the second lead and also covering the first semiconductor element and the second semiconductor element, wherein
the first island is located on a first side in a first direction relative to the second island,
the first semiconductor element is located on a second side in the first direction relative to the first island, and
the second semiconductor element is located on the first side in the first direction relative to the second island.

2. The semiconductor device according to claim 1, further comprising:
a third lead electrically connected to the first semiconductor element; and
a fourth lead electrically connected to the second semiconductor element, wherein
the third lead is located on a first side in a second direction relative to the first island, the second direction being orthogonal to the first direction, and
the fourth lead is located on a second side in the second direction relative to the second island.

3. The semiconductor device according to claim 2, further comprising a first wire connected to the first semiconductor element and the third lead.

4. The semiconductor device according to claim 2, further comprising a second wire connected to the second semiconductor element and the fourth lead.

5. The semiconductor device according to claim 2, wherein the third lead includes a terminal portion protruding from the sealing resin toward the first side in the second direction.

6. The semiconductor device according to claim 2, wherein the fourth lead includes a terminal portion protruding from the sealing resin toward the second side in the second direction.

7. The semiconductor device according to claim 1, wherein the first lead includes a first support portion connected to the first island,
the second lead includes a second support portion connected to the second island,
the first support portion includes a first facing part,
the second support portion includes a second facing part, and
the first facing part and the second facing part face each other in the first direction.

8. The semiconductor device according to claim 7, further comprising a bonding material that bonds the first facing part and the second facing part.

9. The semiconductor device according to claim 1, wherein the first semiconductor element and the second semiconductor element at least partially overlap with each other as viewed in the first direction.

10. The semiconductor device according to claim 1, wherein the first semiconductor element and the second semiconductor element are spaced apart from each other as viewed in the first direction.

11. The semiconductor device according to claim 10, wherein the first semiconductor element and the second semiconductor element at least partially overlap with each other as viewed in a direction orthogonal to the first direction.

12. The semiconductor device according to claim 1, wherein the first island is exposed from the sealing resin to the first side in the first direction.

13. The semiconductor device according to claim 1, wherein the second island is exposed from the sealing resin to the second side in the first direction.

14. The semiconductor device according to claim 1, further comprising a fifth lead including a third facing part and a sixth lead including a fourth facing part, wherein
the third facing part is located on the first side in the first direction relative to the fourth facing part, and
the third facing part and the fourth facing part face each other in the first direction.

15. The semiconductor device according to claim 14, wherein the fifth lead and the sixth lead are insulated from both the first semiconductor element and the second semiconductor element.
